(19) United States
(12) Patent Application Publication
(10) Pub. No.: US 2010/0127707 A1
(43) Pub. Date: May 27, 2010

(54) WEARABLE MAGNETIC RESONATOR FOR MRI RESOLUTION IMPROVEMENT, AND APPLICATION DEVICE INCLUDING THE SAME

(75) Inventors: Wangjoo LEE, Daejeon-city (KR); Dong Ho Kim, Daejeon-city (KR); Jeong Ho Ju, Seoul (KR); Jae Ick Choi, Daejeon-city (KR)

Correspondence Address: AMPACC Law Group, 3500 188th Street S.W., Suite 103, Lynnwood, WA, 98037, US

(73) Assignee: Electronics and Telecommunications Research Institute, Daejeon (KR)

(21) Appl. No.: 12/625,371

(22) Filed: Nov. 24, 2009

(30) Foreign Application Priority Data
Nov. 25, 2008 (KR) 10-2008-0117476

(51) Int. Cl. G01R 33/44

(52) U.S. Cl. 324/318

(57) ABSTRACT

Magnetic resonance imaging (MRI) devices detect a magnetic field having a particular frequency induced by hydrogen nuclei included in a human body and convert the detected magnetic field into two- or three-dimensional images, thereby visualizing the internal structure of the human body without causing any harm to the human body. The higher the resolution of an MRI technique, the more accurate a diagnosis can be obtained. Thus, various methods are introduced to improve resolutions. For example, a wearable magnetic resonator and an application device including the wearable magnetic resonator are provided. The wearable magnetic resonator is flexible and used to improve MRI resolution by amplifying MR signals while being attached to a human body to amplify MR signals when MRI is performed. The wearable magnetic resonator includes the following: a dielectric thin film that is flexible; and a conductor thin film that is disposed to have a split ring resonator (SRR) structure on the dielectric thin film and is flexible, wherein the wearable magnetic resonator includes an inductance component and a capacitance component, and the wearable magnetic resonator amplifies a magnetic field by resonating at a predetermined frequency, thereby improving a MRI resolution.

### CROSS-REFERENCE TO RELATED PATENT APPLICATION

This application claims the benefit of Korean Patent Application No. 10-2008-0117476, filed on Nov. 25, 2008, in the Korean Intellectual Property Office, the disclosure of which is incorporated herein in its entirety by reference.

### BACKGROUND OF THE INVENTION

1. Field of the Invention

The present invention relates to a magnetic resonance imaging (MRI), and more particularly, to a magnetic resonator capable of improving MRI resolution and an application device including the same.

2. Description of the Related Art

A magnetic resonance imaging (MRI) technique is a high-end non-destructive non-radioactive technique that has high efficacy and is not harmful to human bodies. MRI is commonly used to diagnose brain diseases, spinal diseases, bone diseases, joint diseases, cardiovascular diseases, chest diseases, congenital heart diseases, and myocardial infarction. An MRI technique uses the following principle: when a static magnetic field is applied to a human body, hydrogen nuclei included in cell forming molecules attain resonance frequency that is proportional to the intensity of the static magnetic field and easily absorb or emit an electromagnetic wave having the resonance frequency.

MRI devices may visualize the internal structure of a human body based on the principle described above. MRI devices, when a strong static magnetic field having flux density of about 1 Tesla is applied to a measurement site, irradiate a portion of human body with electromagnetic waves of the resonance frequency in a pulse form so as to excite hydrogen nuclei into a high energy state. When the excited hydrogen nuclei return to a low energy state, the hydrogen nuclei release most of their energy in the form of a magnetic field. The emitted magnetic field is a magnetic resonance (MR) signal.

If, when hydrogen nuclei emit a magnetic field, other magnetic fields having different intensities according to position, for example, a gradient magnetic field in which intensity is increased in proportion to a distance in one direction from a reference point, are additionally added to the strong static field, frequencies of magnetic fields emitted by hydrogen nuclei at various positions have derivations proportional to position with respect to a center frequency determined by the static magnetic field. Accordingly, when the MR signals are received by a detector or a receiving antenna and then processed, an image showing a density distribution of hydrogen nuclei can be obtained.

The higher the resolution an MRI technique is, the more accurate a diagnosis can be performed. Thus, during measuring, a signal detector is located as close as possible to human bodies so as to prevent a reduction in MR signals. However, there is always a predetermined interval between human bodies and signal detectors, and in this case, sensitivity is significantly decreased. For example, in cases where surgery is performed while doing real-time MRI, a MR detector used does not contact a human body and is located in a space surrounded by a barrier for preventing permeation of bacteria and thus MR signals detected are reduced in intensity and MRI resolution may be degraded.

Meanwhile, MRI resolutions can be increased by using a magnetic resonator for amplifying MR signals. However, the magnetic resonator also has a limitation on reducing an interval with respect to human bodies. Thus, there is still a need to increase a MRI resolution.

### SUMMARY OF THE INVENTION

The present invention provides a magnetic resonator capable of improving

MRI resolution. The magnetic resonator is attached to a human body and conforms to the shape of the human body. In addition, the location of the magnetic resonator relative to human body needs not be considered by using a plurality of small magnetic resonators simultaneously.

The present invention also provides an application device including the magnetic resonator.

According to an aspect of the present invention, there is provided a wearable magnetic resonator including: a dielectric thin film that is flexible; and a conductor thin film that is disposed to have a split ring resonator (SRR) structure on the dielectric thin film and that is flexible, wherein the wearable magnetic resonator includes an inductance component and a capacitance component, and the wearable magnetic resonator amplifies a magnetic field by resonating at a predetermined frequency, thereby improving magnetic resonance imaging (MRI) resolution. The conductor thin film may be ring-shaped, and may have a gap that is a split portion of the conductor thin film and thus has the capacitance component. For example, the conductor thin film may be circular ring-shaped or square ring-shaped. The dielectric thin film may be interposed between a pair of the conductors, and the gaps of the conductor thin films are disposed on opposite sides.

The conductor thin film may include first and second conductors each being a ring-shaped, wherein the first and second conductors have the same size or different sizes, wherein when the first and second conductors have the same size, the first conductor is disposed on a top surface of the dielectric thin film and the second conductor is disposed on a bottom surface of the dielectric thin film, and when the first and second conductors have different sizes, the second conductor is disposed inside the ring structure of the first conductor, wherein gaps of the first and second conductors are disposed on opposite sides. For example, the conductor thin film may include first and second conductors each being a square ring-shaped, wherein the first and second conductors have the same size and the first conductor is disposed on a top surface of the dielectric thin film and the second conductor is disposed on a bottom surface of the dielectric thin film, and each of the first and second conductors has a gap that is a split portion formed in one side of the corresponding square ring-shaped conductor and thus has the capacitance component. The gap of the first conductor and the gap of the second conductor are disposed on opposite sides. The conductor thin film may also be formed by printing a conductive ink on one surface or opposite surfaces of the dielectric thin film.

According to an aspect of the present invention, there is provided a wearable magnetic resonator assembly including a plurality of the wearable magnetic resonators.

According to an aspect of the present invention, there is provided a magnetic resonator application device including the wearable magnetic resonator or the wearable magnetic resonator assembly. For example, the magnetic resonator application device may be a cloth or portable device that is wearable.

### BRIEF DESCRIPTION OF THE DRAWINGS

The above and other features and advantages of the present invention will become more apparent by describing in detail exemplary embodiments thereof with reference to the attached drawings in which:

FIGS. 1A through 1C are diagrams for explaining operation principles of a split ring resonator (SRR) and a corresponding circuit diagram;

FIGS. 2A through 2D are plan views of possible SRR structures used as wearable magnetic resonators according to embodiments of the present invention;

FIG. 2E is a perspective view of a wearable magnetic resonator according to an embodiment of the present invention;

FIGS. 3A and 3B are images showing flexible products including a wearable magnetic resonator according to an embodiment of the present invention;

FIG. 4A is a diagram for evaluating frequency characteristics of a wearable magnetic resonator according to an embodiment of the present invention;

FIG. 4B is a graph illustrating frequency characteristics when a SRR illustrated in FIG. 4A is used and when a SRR is not used; and

FIG. 5 is a graph illustrating frequency characteristics with respect to various SRRs having different resonance frequencies.

### DETAILED DESCRIPTION OF THE INVENTION

Exemplary embodiments of the present invention will now be described more fully with reference to the accompanying drawings. In regard to the description to be presented, it will be understood that when a layer is referred to as being “on” or “under” another layer, it can be directly on or under the other layer, or intervening layers may also be present. In the drawings, the sizes or shapes of forming elements are exaggerated for convenience for description and clarity, and other forming elements that are not used to describe embodiments of the present invention are not shown. In the drawings, like reference numerals denote like elements. Meanwhile, terms are used in descriptive sense only and not for purposes of limitations on meanings or the scope of the present invention defined in the claims.

A magnetic resonator according to the present invention is a type of split ring resonator (SRR) capable of amplifying a magnetic resonance (MR) signal by being attached to a human body. SRRs resonate when an external magnetic field corresponding to a self resonance frequency is applied to the SRRs and amplify the magnetic field. Hereinafter, an SRR and a magnetic resonator will be used as the same concept.

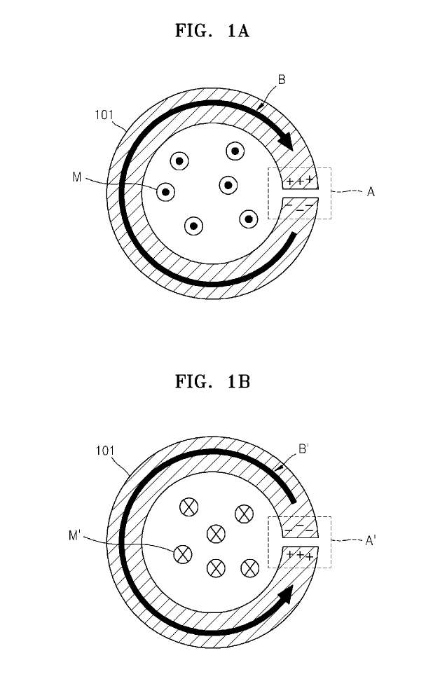

FIGS. 1A through 1C are diagrams for explaining operation principles of a split ring resonator (SRR) and a corresponding circuit diagram.

Referring to FIGS. 1A and 1B, the SRR includes a conductor (101) that is ring-shaped and has a split portion, that is, a gap A. The conductor (101) may be disposed on a dielectric thin film (not shown.) The SRR operates based on the following principles:

When the intensity of an external magnetic field M that penetrating perpendicularly through the conductor (101) is changed, an induced current B may flow along a circumferential direction of the conductor (101) according to an electromagnetic rule and the induced current also induces magnetic field that passes through and is perpendicular to the conductor (101). Since the conductor (101) has an inductance component, L, and the gap A has a capacitance component, C, the entire structure of the conductor (101) may be modeled as an L-C resonance circuit. Thus, by appropriately controlling L and C, resonance may be obtained at a desired frequency. A resonance frequency fᵣ of the L-C resonance circuit may be obtained using Equation 1.

fᵣ=1/{2π(LC)^{1/2}} Equation 1

Meanwhile, as described above, if the frequency of the external magnetic field M is similar to the resonance frequency fᵣ, a high induced current flows and thus a high induced magnetic field is generated, thereby amplifying a magnetic field. Referring to FIG. 1A, the external magnetic field M is amplified in a direction upwards through the paper.

Referring to FIG. 1B, unlike as illustrated in FIG. 1A, an induced current and other elements when the external magnetic field M′ is amplified in a direction downwards through the paper are illustrated, and it can be seen that polarities of an induced current B′ is opposite to polarities of an induced current B illustrated in FIG. 1A.

In FIG. 1C, the SRR illustrated in FIGS. 1A and 1B may be modeled as a circuit diagram, that is, an equivalent RLC circuit. Since the conductor (101) can have a resistance component R, which was not described before, a RLC circuit may be a more accurate equivalent circuit than a LC circuit.

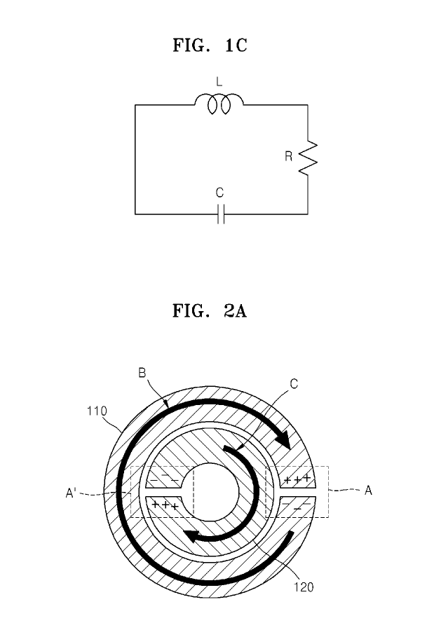

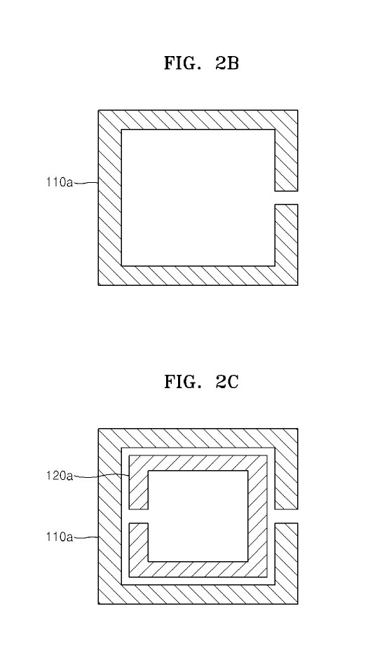

FIGS. 2A through 2D are plan views of possible SRR structures that may be used as wearable magnetic resonators according to embodiments of the present invention.

Referring to FIG. 2A, a SRR according to the present embodiment includes, unlike as illustrated in FIG. 1A or FIG. 1B, first and second conductors 110 and 120 that are ring-shaped and that are disposed on a dielectric thin film (not shown). The first and second conductors 110 and 120 are disposed as concentric circle on the same plane. The first and second conductors 110 and 120 have split portions, that is, gaps A and A′, respectively. Meanwhile, the first conductor 110 is disposed outside the second conductor 120, and the gap A of the first conductor 110 and the gap A′ of the second conductor 120 are located on opposite sides.

Unlike the SRR structure including a single conductor ring as illustrated in

FIG. 1A or FIG. 1B in which a capacitance component is generated only in a split portion of the single conductor ring corresponding to the gap, for a SRR including two conductor rings as described in the present embodiment, a capacitance component is further generated between the rings, that is, between the first conductor 110 and the second conductor 120 and thus, a resonance frequency may be easily lowered. In addition, since charges accumulated around the gaps A and A′ have opposite polarities, overall, polarization due to charge accumulation does not occur. Although not illustrated, an external magnetic field is amplified in a direction through the paper, and therefore, induced currents B and C of the first and second conductors 110 and 120, respectively, flow in the same direction.

FIG. 2B is a plan view of a SRR according to another embodiment of the present invention. That is, a ring-shaped conductor 110a, unlike the SRR illustrated in FIG. 1A or FIG. 1B, has a square shape, not the circular shape in FIG. 1A or 1B. However, the SRR illustrated in FIG. 2B is functionally the same as the SRRs illustrated in FIGS. 1A and 1B.

FIG. 2C is a plan view of a SRR according to another embodiment of the present invention. The SRR illustrated in FIG. 2C is the similar to that as illustrated in FIG. 2A, except that the first and second conductors 110 and 120 having a circular-ring shape are replaced with two conductors 110a and 120a having a square-ring shape. That is, gaps are disposed on opposite sides, and corresponding sides are disposed in parallel. Thus, the resultant effect is similar to the effect that has been described with reference to FIG. 2A.

FIG. 2D is a plan view of a SRR that is designed by modifying the SRR illustrated in FIG. 2C. First and second conductors 110b and 120b each include two gaps. In each of the first and second conductors 110b and 120b, the gaps are located on opposite sides. The gaps of the first conductor 110b are located in a direction perpendicular to the gaps of the second conductor 120b. That is, a portion in which the gaps of the first conductor 110b are formed is not parallel to a portion in which the gaps of the second conductor 120b.

FIG. 2E is a perspective view of a wearable magnetic resonator according to another embodiment of the present invention. Especially FIG. 2E shows a conductor-dielectric-conductor sandwiched SRR and the shape of SRRs are not limited thereto.

FIG. 2E is a three-dimensional view of a SRR. Unlike the SRRs illustrated in FIG. 2A˜2D, two conductors 210a and 210b are respectively disposed on top and bottom surfaces of a dielectric 220. In each of the conductors 210a and 210b, gaps are located on opposite sides.

Hereinbefore, various SRRs are exemplarily illustrated, but a SRR according to an embodiment of the present invention is not limited thereto. For example, although the conductors illustrated in FIGS. 1A and 2A through 2D are described as being disposed on the same plane, a dielectric thin film may be interposed between a pair of the same conductors. As described above, when conductors are respectively disposed on top and bottom surfaces of a dielectric thin film, the conductors have the same shape and a gap of the conductor disposed on the top surface of the dielectric thin film and a gap of the conductor disposed on a bottom surface of the dielectric thin film are located on opposite sides. Meanwhile, although the shape of a conductor is circular and square in the previous embodiments, the shape of the conductor may also have other shapes.

Various SRRs according to the previous embodiments, that is, magnetic resonators may be implemented by a flexible thin film structure by using a flexible thin conductor film and a flexible dielectric thin film. Such a magnetic resonator having flexibility may be attached to and placed as close as possible to or contacting a human body regardless of the surface shape or location of the human body, and thus, a MR signal can be effectively amplified and thus, a MRI resolution may be significantly improved.

For reference, the SRRs as described above are researched as being a part of a meta-material having a negative refractive index with respect to an electromagnetic wave rather than being applied in particular technical application fields [J. B. Pendry, A. J. Holden, D. J. Robbins, and W. J. Stewart, “Magnetism from conductors and enhanced nonlinear phenomena,” IEEE Trans. on Microwave theory and tech., Vol. 47, No. 11, Nov., 1999.]. Conventionally, SRRs are formed in a usual printed circuit board (PCB) which is a hard device. However, according to the present invention, a SRR is manufactured using a flexible dielectric film with thin conductor films on both sides of it. Thus, the SRR is very flexible and can be directly attached to a human skin, or SRR-including clothes or portable devices can be manufactured and humans can wear them. By doing so, when MR signals are captured, the magnetic field is amplified and high resolution can be obtained.

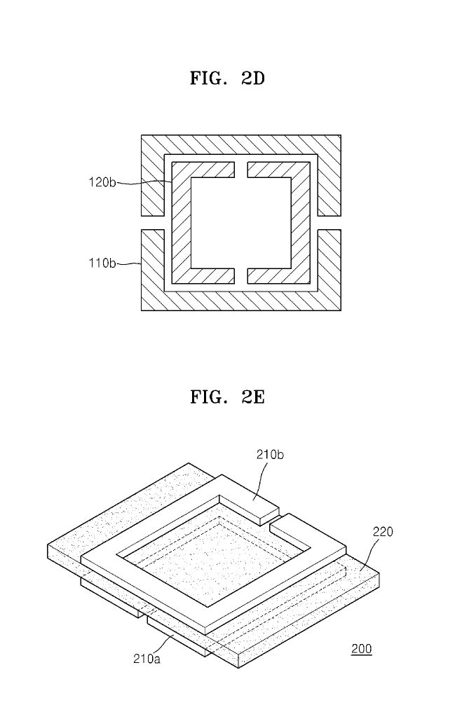

FIGS. 3A and 3B are images showing flexible products including a wearable magnetic resonator according to an embodiment of the present invention.

Referring to FIG. 3A, highly flexible wearable magnetic resonators are implemented as products. Each of the magnetic resonators employs the SRR structure illustrated in FIG. 2E. That is, a dielectric thin film is interposed between rectangular ring-shaped conductor thin films. In an actual experiment, a cooking aluminum foil was used as the rectangular ring-shaped conductor thin films and a cooking wrap was used as the dielectric thin film. The thickness of the dielectric thin film was about 100 μm or less.

FIG. 3B is an image of a finger covered with a magnetic resonator manufactured in the same manner as described with reference to FIG. 3A to explain flexibility characteristics. As described above, a magnetic resonator according to the present invention includes a flexible conductor and a flexible dielectric thin film and thus, can be easily attached to any position of a human body.

As described with reference to FIG. 3A or FIG. 3B, flexible magnetic resonators can be manufactured by attaching thin conductor film to a thin dielectric film. However, magnetic resonators can also be manufactured using other methods. For example, a conductive ink may be printed in various conductor patterns on one surface or opposite surfaces of a flexible dielectric thin film formed of poly vinyl chloride or polypropylene that is used as the base material of scotch tape, thereby obtaining the SRRs illustrated in FIGS. 1A and 2A through 2E.

Meanwhile, although not illustrated, each of the SRRs illustrated in FIGS. 1A and 2A through 2E can also be disposed as a unit in various ways, for example, in an array, thereby forming a SRR assembly. A SRR assembly may be used in various products that are easily attached to a human body, such as clothes or portable devices.

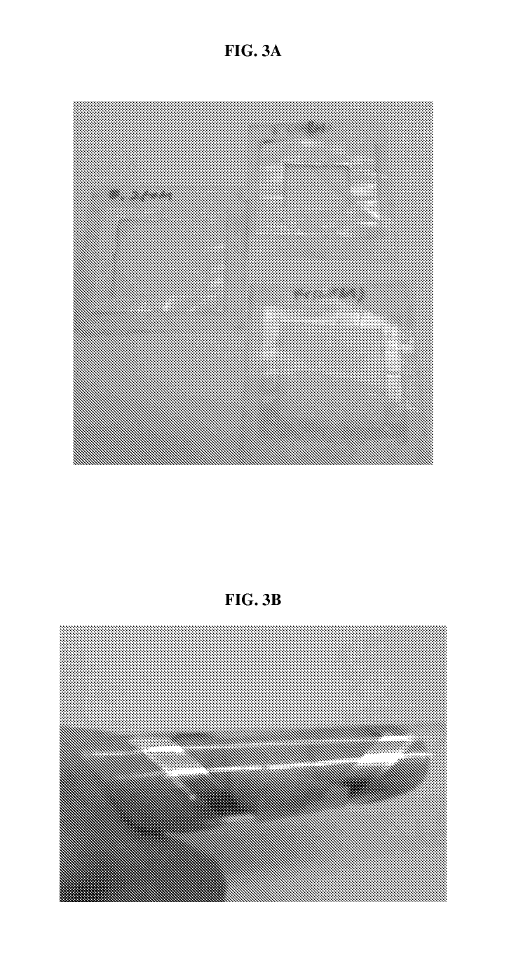

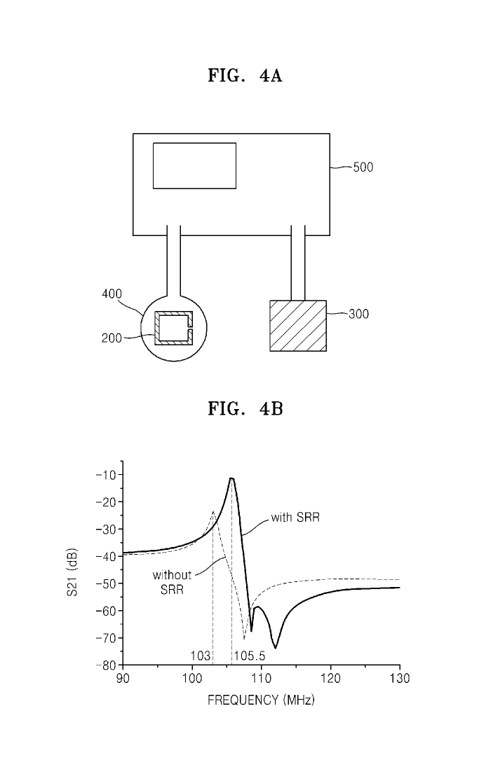

FIG. 4A is a diagram for evaluating frequency characteristics of a wearable SRR according to an embodiment of the present invention.

The wearable SRR (200) has the structure illustrated in FIG. 2E, and a network analyzer (500) drives the loop antenna (400) and generates an oscillating magnetic field. In addition, an oscillating magnetic field detector (300) which has resonant frequency of 103 MHz is disposed near the loop antenna (400) detects the generated magnetic field. Specifically, the loop antenna (400) and the SRR (200) have the same center on the same plane, and the magnetic field detector (300) is disposed parallel to the loop antenna (400) and the SRR (200) plane, and is separated from the loop antenna (400) and the SRR (200) by a distance of about 10 cm.

FIG. 4B is a graph illustrating frequency transfer characteristics when the SRR (200) illustrated in FIG. 4A is used and when the SRR 200 is not used. In FIG. 4B, the x-axis represents frequency and the y-axis represents a gain (S21).

Referring to FIG. 4B, when the SRR (200) is used, the maximum gain is increased by around at least 10 dB or more, compared to when the SRR (200) is not attached to the loop antenna 400. The results show that the SRR (200) amplifies the generated magnetic field. Although the frequency corresponding to the maximum gain is shifted from 103 MHz to 105.5 MHz, when MRIs are actually captured, the frequency change can be controlled by adjusting a resonance frequency of the SRR (200) in such a way that the maximum gain appears at any signal frequency at which a measurement is performed. Since the inductance of SRR is proportional to the enclosed area of the conductor ring and the capacitance is proportional to the permittivity and the inverse thickness of the dielectric film and also depends on the split gap width, the resonance frequency can be controlled by adjusting these parameters.

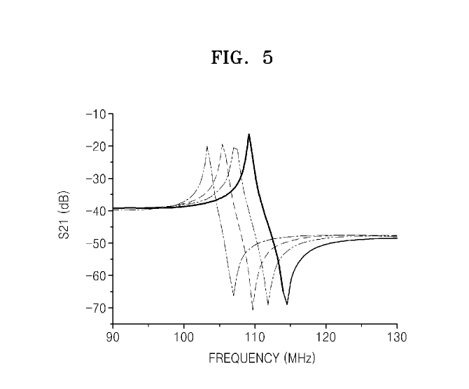

FIG. 5 is a graph illustrating frequency characteristics with respect to various SRRs having different resonance frequencies.

As illustrated in FIG. 5, it can be seen that different frequency characteristics are obtained by adjusting a resonance frequency of a SRR. That is, the resonance frequency can be controlled in such a way that the maximum gain appears at any particular signal frequency at which measurement is performed.

For a wearable magnetic resonator capable of improving MRI resolutions according to the present invention and an application device including the same, a highly flexible SRR may be used, and thus, the wearable magnetic resonator can be attached to and located conforming to the shape of a human body. In addition, a relative location between the human body and the wearable magnetic resonator need not to be considered by using a plurality of the small wearable magnetic resonators. Therefore, since MRIs can be captured while the wearable magnetic resonator is attached to the human body, MR signals can be effectively amplified and MRI resolutions can be significantly improved.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A wearable magnetic resonator comprising:
a dielectric thin film that is flexible; and
a conductor thin film that is disposed to have a split ring resonator (SRR) structure on the dielectric thin film and that is flexible,
wherein the wearable magnetic resonator comprises an inductance component and a capacitance component, and the wearable magnetic resonator amplifies a magnetic field by resonating at a predetermined frequency, thereby improving magnetic resonance imaging (MRI) resolution.

2. The wearable magnetic resonator of claim 1, wherein the conductor thin film is ring-shaped, and has a gap that is a split portion of the conductor thin film and thus has the capacitance component.

3. The wearable magnetic resonator of claim 2, wherein the conductor thin film is circular ring-shaped or square ring-shaped.

4. The wearable magnetic resonator of claim 2, wherein the dielectric thin film is interposed between a pair of the conductor thin films, and the gaps of the conductor thin films are disposed on opposite sides.

5. The wearable magnetic resonator of claim 2, wherein the conductor thin film comprises first and second conductors each being a ring-shaped,
wherein the first and second conductors have the same size or different sizes,
wherein when the first and second conductors have the same size, the first conductor is disposed on a top surface of the dielectric thin film and the second conductor is disposed on a bottom surface of the dielectric thin film, and when the first and second conductors have different sizes, the second conductor is disposed inside the ring structure of the first conductor,
wherein gaps of the first and second conductors are disposed on opposite sides.

6. The wearable magnetic resonator of claim 1, wherein the conductor thin film comprises first and second conductor thin films each being a circular ring-shaped and each of the first and second conductors has a gap that is a split portion of the corresponding conductor and thus has the capacitance component, and
the second conductor is disposed inside the circular ring structure of the first conductor and the gap of the first conductor and the gap of the second conductor are disposed on opposite sides.

7. The wearable magnetic resonator of claim 1, wherein the conductor thin film comprises first and second conductors each being a square ring-shaped and each of the first and second conductors has a gap that is a split portion formed in one side of the corresponding square ring-shaped conductor, and
the second conductor is disposed inside the square ring structure of the first conductor and the gap of the first conductor and the gap of the second conductor are disposed on opposite sides.

8. The wearable magnetic resonator of claim 1, wherein the conductor thin film comprises first and second conductors each being a rectangular ring-shaped and each of the first and second conductors has gaps that are split portions formed in facing sides of the total four sides of the corresponding rectangular ring-shaped conductor and thus has the capacitance component, and
the second conductor is disposed inside the rectangular ring structure of the first conductor and the facing sides having the gaps of the first conductor are not parallel to the facing sides having the gaps of the second conductor.

9. The wearable magnetic resonator of claim 1, wherein the conductor thin film comprises first and second conductors, wherein the first and second conductors have the same size and the first conductor is disposed on a top surface of the dielectric thin film and the second conductor is disposed on a bottom surface of the dielectric thin film,
the first and second conductors have a ring shape and each of the first and second conductors has a gap that is a split portion formed in one side of the corresponding ring shaped conductor, and
the gap of the first conductor and the gap of the second conductor are disposed on opposite sides.

10. The wearable magnetic resonator of claim 1, wherein the conductor thin film is formed by printing a conductive ink on one surface or opposite surfaces of the dielectric thin film.

11. A wearable magnetic resonator assembly comprising a plurality of the wearable magnetic resonators of claim 1.

12. The wearable magnetic resonator assembly of claim 11, wherein each of the wearable magnetic resonators comprises:
a dielectric thin film that is flexible; and
a conductor thin film that is disposed to have a split ring resonator (SRR) structure on the dielectric thin film and is flexible,
wherein the conductor thin film is ring-shaped, and has a gap that is a split portion of the conductor thin film and thus has the capacitance component.

13. The wearable magnetic resonator assembly of claim 12, wherein the dielectric thin film is interposed between a pair of the conductor thin films, and the gaps of the conductor thin films are disposed on opposite sides.

14. The wearable magnetic resonator assembly of claim 12, wherein the conductor thin film comprises first and second conductors that are ring-shaped,
wherein the second conductor is disposed inside the ring-structure of the first conductor, and
gaps of the first and second conductors are disposed on opposite sides.

15. A magnetic resonator application device comprising the wearable magnetic resonator of claim 1 or the wearable magnetic resonator assembly of claim 11.

16. The magnetic resonator application device of claim 15, wherein the magnetic resonator application device is a cloth or portable device that is wearable.
